(19) United States
(12) Patent Application Publication
(10) Pub. No.: US 2005/0016470 A1
(43) Pub. Date: Jan. 27, 2005

(54) Susceptor and deposition apparatus including the same

(76) Inventors: Tae-Soo Kang, Yongin-si (KR); Soo-Yeol Choi, Osani-si (KR); Kyoo-Chul Cho, Youngin-si (KR); Gi-Jung Kim, Yongin-si (KR); Jin-Ho Kim, Seoul (KR); Tae-Yeol Heo, Youngin-si (KR)

Correspondence Address: VOLENTINE FRANCOS, P.L.L.C.;Suite 150, 12200 Sunrise Valley Drive, Reston, VA, 20191, US

(21) Appl. No.: 10/898,306

(22) Filed: Jul. 26, 2004

(30) Foreign Application Priority Data
Jul. 25, 2003 (KR) 2003-51637

(51) Int. Cl. C23C 16/00

(52) U.S. Cl. 118/728

(57) ABSTRACT

A susceptor for use in a deposition apparatus includes a recess in which a wafer is received, and a stress-reducing bumper disposed along the side of the recess. The stress-reducing bumper is of material having ductility at a relatively high temperature. Therefore, when the wafer contacts the stress-reducing bumper, such as may occur due to thermal expansion of the wafer during processing, the force of the impact on the wafer is minimized by an elastic deformation of the stress-reducing bumper. As a result, defects, such as slip dislocations at the outer peripheral edge of the wafer, are prevented.

### BACKGROUND OF THE INVENTION

1. Field of the Invention

The present invention relates to a susceptor of a deposition apparatus. More particularly, the present invention relates to a susceptor used in a chemical vapor deposition apparatus for forming an epitaxial layer.

2. Description of the Related Art

The quality of a silicon wafer used as a substrate in the fabricating of a highly integrated semiconductor device greatly affects the yield and reliability of the semiconductor device. The quality of the silicon wafer is dependent on the distribution and density of internal or external defects such as those generated on a surface of the silicon wafer during the manufacturing of the silicon wafer.

Generally, a silicon wafer is fabricated as follows. First, a polycrystalline silicon ingot is formed. The polycrystalline silicon ingot is grown by a Czochoralski (CZ) method or a floating zone (FZ) method to form a single crystalline silicon ingot. The single crystalline silicon ingot is cut into thin sections. Each section of the cut single crystalline silicon ingot is polished and cleaned to form a silicon wafer. However, defects such as a D-effect defect, crystal original particles (COPs) and a conductive oxide are frequently generated during the fabricating of the silicon wafer.

Accordingly, an epitaxial wafer has been developed to provide a silicon wafer having a surface on which the above-described defects do not exist. An epitaxial wafer includes a silicon wafer on which single crystalline silicon is formed by an epitaxial growth process. However, the epitaxial growth process is performed at a high temperature of above about 1,000° C. Therefore, a thermal stress is created in the wafer during the epitaxial growth process. As a result, a slip dislocation may occur in the silicon wafer when the wafer experiences even a small physical impact. The slip dislocation is caused by silicon atoms slipping in the silicon wafer which, in turn, manifests itself as a surface defect in the silicon wafer.

Hereinafter, the slip dislocation that is produced in the silicon wafer as a result of the epitaxial growth process will be explained in more detail.

FIGS. 1 and 2 are cross-sectional views of a susceptor employed in a conventional epitaxial deposition apparatus.

Referring FIG. 1, a conventional susceptor includes a plate 12 having a recess 14 for receiving a wafer W. The outer periphery of the bottom of the recess 14 has a rounded shape to minimize the area of contact between the plate 12 and the wafer W. Accordingly the susceptor contacts only an edge of the wafer W once the wafer W has been loaded into the susceptor 10 as received in the recess 14.

Also, at this time, the outer peripheral edge of the wafer W is spaced apart from an inner wall of the plate 12 that defines the side of the recess 14. In particular, there is a gap d1 between the outer peripheral edge of the wafer W and the inner wall of the plate 12 to prevent the outer peripheral edge of the wafer W from contacting the plate 12. The gap d1 is designed for on the basis of the coefficients of thermal expansion of the wafer W and the plate 12. In general, the susceptor and the wafer W are heated at a relatively high temperature of about 1,000° C. during the deposition process so that the inner wall of the plate 12 may thermally expanded inwardly, whereas the wafer W may thermally expand outwardly.

However, the precise amounts of the thermal expansions of the wafer W and the plate 12 can not be readily calculated. Also, the sizes of the silicon wafers are irregular. Moreover, accurately controlling the temperature in the deposition process is substantially difficult.

Referring to FIG. 2, the wafer W may contact the inner wall of the plate 12 during the deposition process regardless of the gap d1 that is designed for between the wafer W and the inner wall of the plate 12 that defines the side of the recess 14. Additionally, the susceptor is rotated in a horizontal plane during the deposition process so that the layer formed on the wafer W is made uniform. Accordingly, the wafer W may be moved into contact with the inner wall of the plate 12 by the centrifugal force generated by the rotation of the susceptor.

When the wafer W and the plate 12 contact each other and are expanded in opposite directions towards each other during the deposition process, i.e., while at a relatively high temperature, slip dislocations 16 may occur in the edge of the substrate due to the physical impact between the wafer W and the inner wall of the plate 12. Furthermore, the slip dislocations 16 may occur in the edge of the epitaxial layer formed by the deposition process.

When a semiconductor device is formed on an epitaxial wafer having slip dislocations, the semiconductor device may not operate normally or may have low reliability.

### SUMMARY OF THE INVENTION

An object of the present invention is to provide a susceptor for minimizing slip dislocations of a wafer.

Similarly, another object of the present invention is to provide a deposition apparatus for forming an epitaxial layer on wafer while minimizing slip dislocations of the wafer.

In accordance with one aspect of the present invention, a susceptor includes a plate having a recess in which a wafer is received, and a ductile stress-reducing bumper disposed along a side of the recess.

In accordance with another aspect of the present invention, a deposition apparatus includes a chamber in which a deposition process is performed, and a susceptor disposed in the chamber, the susceptor including a plate having at least one recess in which a wafer is received, and a ductile stress-reducing bumper disposed along the side of the recess. A heater block for heating the susceptor is disposed under the susceptor or in the chamber for heating the wafer(s). A gas inlet pipe is connected to the chamber for introducing deposition source gas into the chamber. A gas outlet pipe is also connected to the chamber for exhausting gas from the chamber.

According to the present invention, although the wafer may come into contact with the susceptor during the deposition process, the ductile stress-reducing bumper minimizes the physical impact between the susceptor and the wafer. Therefore, slip dislocations are not produced, especially at the outer peripheral edge of the wafer.

### BRIEF DESCRIPTION OF THE DRAWINGS

The above and other features and advantages of the present invention will become readily apparent from the following detailed description thereof made in conjunction with the accompanying drawings, of which:

FIGS. 1 and 2 are cross-sectional views of a susceptor of a conventional epitaxial deposition apparatus;

FIGS. 3 and 4 are cross-sectional views of a first embodiment of a susceptor in accordance with the present invention;

FIG. 5 is an enlarged view of a portion A of the susceptor in FIG. 4;

FIG. 6 is a plan view of the first embodiment of the susceptor in accordance with the present invention;

FIG. 7 is a cross-sectional view of a second embodiment of a susceptor in accordance with the present invention;

FIG. 8 is a cross-sectional view of a deposition apparatus in accordance with the present invention; and

FIG. 9 is a cross-sectional view of another embodiment of a deposition apparatus in accordance with the present invention.

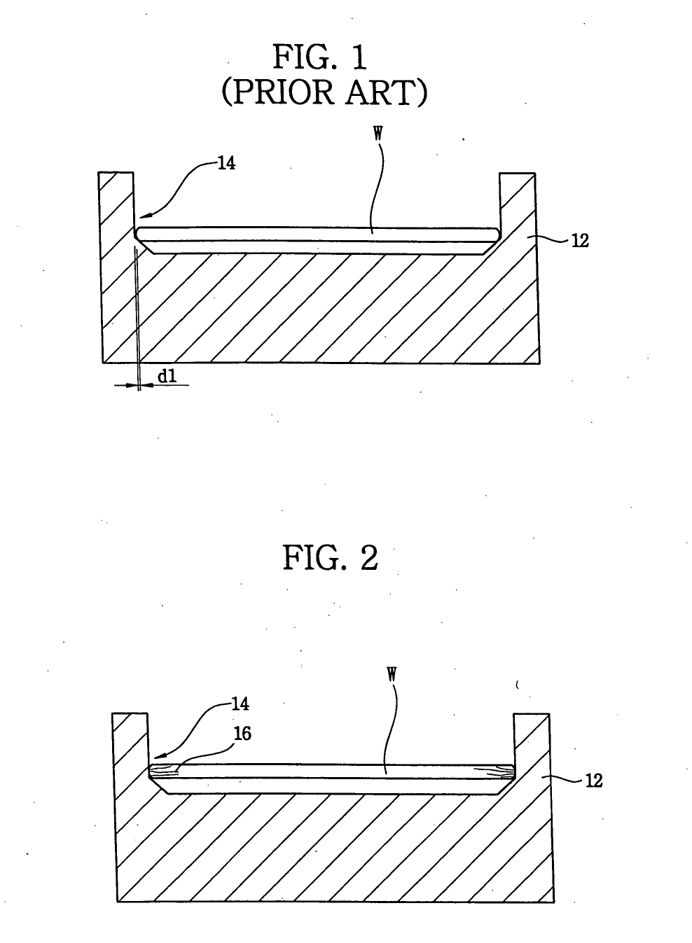

### DETAILED DESCRIPTION OF THE PREFERRED EMBODIMENTS

The present invention now will be described more fully hereinafter with reference to the accompanying drawings.

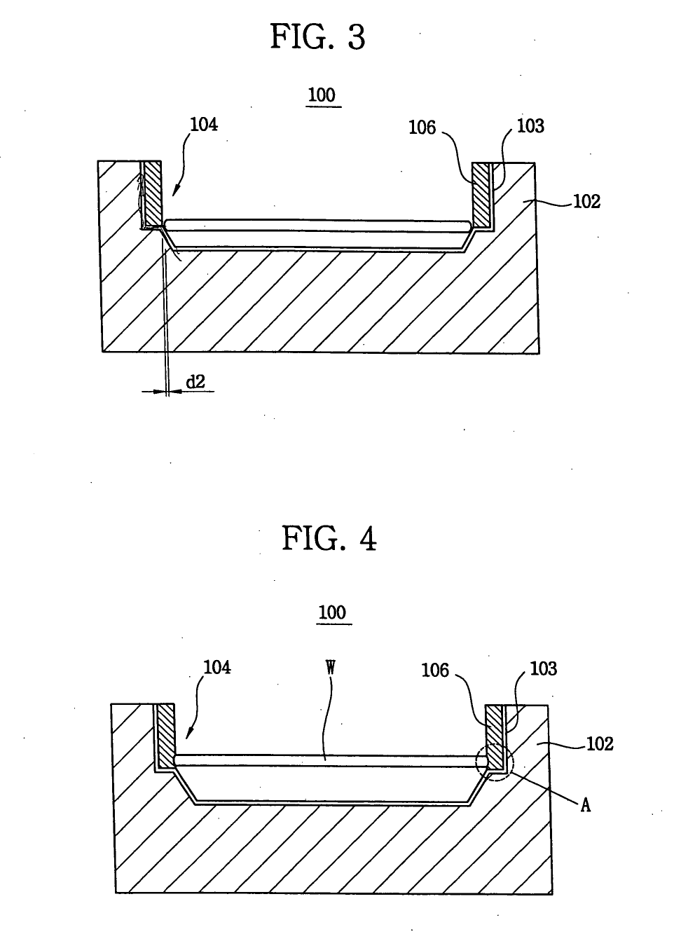

Referring now to FIG. 3, a susceptor 100 is provided in a deposition chamber. The susceptor 100 includes a plate 102. The plate 102 has a recess 104 in an upper portion thereof. A wafer W is received in the recess 104 during a process in which a layer is formed on the wafer.

The plate 102 may have only one recess 104 in the upper portion thereof. Alternatively, as shown in FIG. 6, the plate 102 may have a plurality of recesses 104 each configured to accommodate a respective wafer W. Preferably, the recesses 104 each have a circular sectional shape in a plane parallel to the upper surface of the plate 12, and are spaced from one another in that plane or lie tangentially with respect to one another as shown in the figure. Thus, layers may be simultaneously formed on a plurality of the wafers W when the susceptor 100 of FIG. 6 is employed in the deposition chamber.

The plate 102 is formed of a material that can withstand temperatures of above about 1,000° C. so as to be suitable for use during the deposition process. The material preferably has a high melting point and mechanical properties, such as strength, hardness, etc., that do not vary under high temperatures. For example, the plate 102 may include a material including carbon, e.g., graphite. However, a silicon carbide (SiC) layer 103 is preferably formed at the surface of the plate 102 when the plate 102 includes carbon to prevent the wafer from being contaminated by the carbon of the plate 102.

The bottom of the recess 104 has a rounded shape especially at the outer periphery thereof. In particular, the recess 104 has a frusto-conical bottom portion and a cylindrical top portion extending upwardly from the bottom portion. The bottom portion of the recess 104 is delimited by an inner bottom wall at the bottom center of the recess 104, and an inclined inner side wall of the plate 102 that extends from and subtends an obtuse angle with the bottom wall. The top portion of the recess 104 is delimited by an inner upright side wall of the plate 102 that extends to the upper surface of the plate 12, and another bottom wall that extends substantially perpendicular to the inner upright side wall of the plate 102. Accordingly, the bottom surface of the wafer will not contact the inner intermediate side wall of the plate 102, that defines the side of the recess 104, due to the inclined inner side wall that defines the bottom portion of the recess 104.

A stress-reducing bumper 106 is disposed in the upper portion of the recess 104 as facing the inner upright side wall and second bottom wall that define the upper portion of the recess 104. In general, the stress-reducing bumper is annular and has a uniform thickness in the radial direction thereof. The stress-reducing bumper 106 includes a material having a significant amount of ductility at the deposition temperature. At the very least, the stress-reducing bumper is more ductile at the deposition temperature, e.g., of about 1000° C., than the upright inner side wall of the plate 102 that delimits the side of the recess 104. In addition, a gap d2 is provided between the stress-reducing bumper 106 and the outer peripheral side edge of the wafer W received in the recess 104. Therefore, the wafer W will preferably not contact the stress-reducing bumper 106 even when the wafer W thermally expands under the high temperature of the deposition process.

Generally, a change in length of an object due to thermal expansion can be calculated using the following equation:
Δl=α·l₀·ΔT
wherein α represents the coefficient of thermal expansion of the object, l₀ represents the initial length of the object, and ΔT represents the change in temperature experienced by the object.

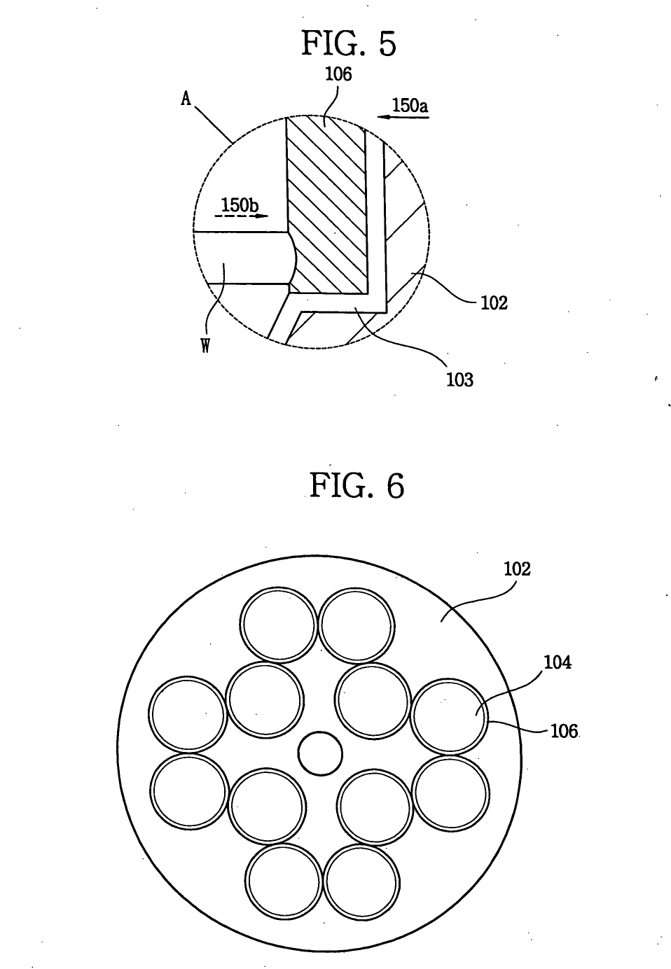

Referring to FIG. 4, although the present invention contemplates that a sufficient margin (gap d2) is provided between the wafer W and the stress-reducing bumper 106, the wafer W may nonetheless contact the stress-reducing bumper 106 in the deposition chamber when the temperature rises to a value in excess of above about 1,000° C. That is, as shown in FIG. 5, when the susceptor 100 and the wafer W are heated to a temperature of above about 1,000° C., the plate 102 may expand whereupon the inner side walls of the plate 102 that define the side of the recess 104 move radially inwardly of the recess 104 in the direction of arrow 150a, whereas the wafer W may expand in a direction radially outwardly of the recess 104 in the direction of arrow 150b. When the wafer W contacts the stress-reducing bumper 106, a minimal impact is exerted on the wafer W.

To this end, the stress-reducing bumper 106 is advantageously formed of material whose strength and hardness decrease above a certain temperature. Therefore, the impact on the wafer W may be minimized by the elasticity of the stress-reducing bumper 106, which elasticity increases as the temperature in the deposition chamber approaches the deposition temperature. Also, the stress-reducing bumper 106 is preferably formed of material having a high melting point and producing little, when any contaminants, at a temperature of above about 1,000° C. For example, the stress-reducing bumper 106 may include quartz glass. Quartz glass is thermally stable. Moreover, quartz glass will not generate particles that could contaminate the deposition chamber.

Still further, as the temperature of quartz glass rises to above its transition temperature, the single-crystal structure of the quartz glass turns into an amorphous structure wherein the strength and hardness of the quartz glass decrease remarkably. Accordingly, the impact on the wafer W is minimal at a temperature of about 1,000° C. when the stress-reducing bumper 106 is of quartz glass because 1,000° C. is above the transition temperature of the quartz glass and hence, the wafer W will compress the amorphous structure of the quartz glass rather easily. Additionally, quartz glass has a viscosity of above 1015 dynes/cm² at a temperature of about 1,000° C. Therefore, the shape of the stress-reducing bumper 106 will not be permanently modified, i.e., the quartz glass experiences elastic as opposed to plastic deformation.

Consequently, defects usually caused by an impact between the wafer W and the susceptor 100 are minimized when the stress-reducing bumper 106 according to the present invention is used. Examples of the defects include slip dislocations that occur at the edge of the wafer W, etc. As a result, the reliability of a semiconductor device formed on the wafer W is improved.

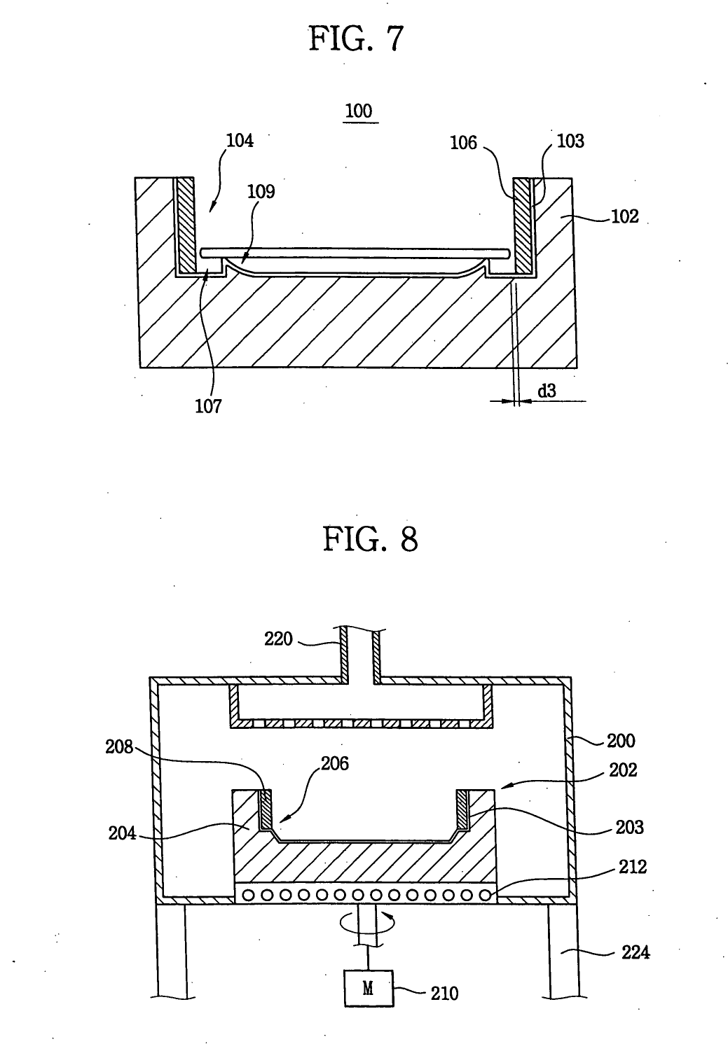

FIG. 7 illustrates another susceptor in accordance with the present invention. Referring to FIG. 7, the susceptor 100 includes a plate 102 having a recess 104 in the top thereof. The bottom of the recess 104 also has a rounded shape especially at the outer periphery thereof. More specifically, the plate 102 has first a bottom wall, and a projection 109 at the outer periphery thereof. A wafer is seated on the projection 109 when it is loaded into the recess 104 of the susceptor 100. Accordingly, the wafer does not contact with the bottom wall of the plate 102.

Also, the recess 104 includes a groove 107 that extends around the projection 109 at the bottom of the recess 104. The groove 107 is delimited by the projection 109, an upright inner side wall of the plate 102 that delimits the side of the recess 104, and a second bottom wall of the plate 102 that extends between the projection 109 and upright inner side wall of the plate 102. The second bottom wall extends substantially perpendicular to the upright inner side wall of the plate 102.

A stress-reducing bumper 106 is disposed along the upright inner side wall of the plate 102 that defines the side of the recess 104. The stress-reducing bumper 106 is of material having a significant amount of viscosity at a high temperature. The stress-reducing bumper 106 also extends within the groove 107. The width of the groove 107 is greater than the thickness of the stress-reducing bumper 106 so that a portion of the groove 107 is exposed at one side of the stress-reducing bumper 106.

A gap d3 is designed to be left between the stress-reducing bumper 106 and the side of a wafer received in the recess 104. Although the present invention contemplates that gap d3 provided between the wafer and the stress-reducing bumper 106 is sufficient to prevent the wafer from contacting the stress-reducing bumper 106, the wafer may nonetheless contact the stress-reducing bumper 106 in the deposition chamber when the temperature rises to a value in excess of above about 1,000° C. However, the stress-reducing bumper 106 include quartz glass that is significantly ductile at a high temperature. Consequently, minimal defects, such as slip dislocations at the edge of the wafer, are caused by an impact between the wafer and the susceptor 100.

FIG. 8 illustrates a deposition apparatus in accordance with the present invention. The deposition apparatus is used to form a layer on a substrate at a temperature of above 1,000° C. One example of such a layer is a silicon epitaxial layer.

Referring FIG. 8, the deposition apparatus includes a deposition chamber 200 in which the deposition process is performed. A susceptor 202 onto which a silicon wafer W is loaded is disposed in the process chamber 200. The susceptor 202 includes a plate 204 and a stress-reducing bumper 208. The plate 204 has one or more recesses 206 in which a wafer is/are received. The stress-reducing bumper 208 is disposed along the side of the recess 206 and includes material that is ductile at a high temperature. Preferably, the stress-reducing bumper 208 is of quartz glass.

Each recess 206 of the susceptor 202 has a shape that is substantially identical to that of the first embodiment shown in FIGS. 2-5. Thus, the bottom of the recess 206 has a rounded shape so that only a small portion of the wafer W contacts the plate 204 within the recess 206. The plate 204 preferably includes carbon, and a silicon carbide (SiC) layer 203 formed on a surface of the plate 204 that defines the recess 206.

A drive mechanism comprising a motor 210 is connected to the susceptor 202 for rotating the susceptor 202 in a horizontal plane. A heater 212 for heating the wafer W is disposed at a lower portion of the susceptor 202.

A gas inlet pipe 220 and showerhead or the like are connected to the deposition chamber 200 so that deposition source gas is introduced into the deposition chamber 200 through the gas inlet pipe 220. A gas outlet pipe 224 is connected to the deposition chamber 200 so that by-products generated in the deposition chamber 200 are exhausted from the deposition chamber 200 through the gas outlet pipe 224.

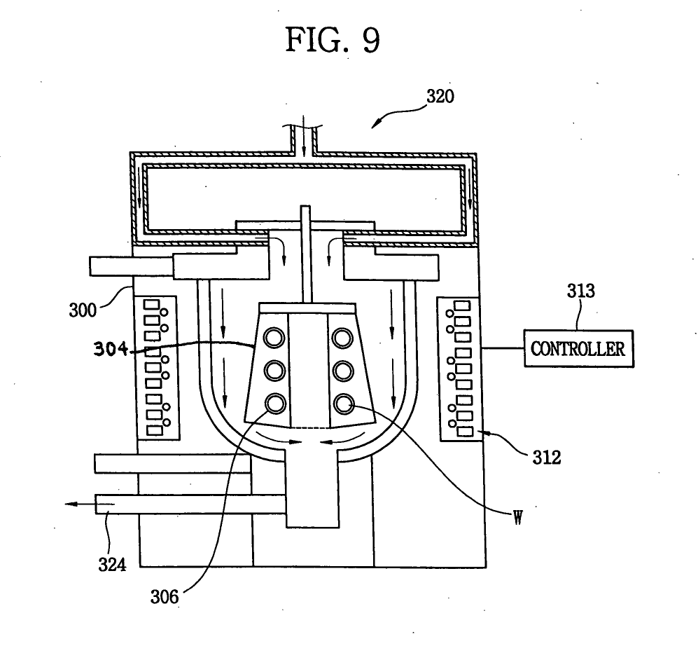

FIG. 9 illustrates another embodiment of a deposition apparatus in accordance with the present invention. This deposition apparatus is a batch type of deposition apparatus for simultaneously processing a plurality wafers.

Referring FIG. 9, a susceptor configured to support a plurality of silicon wafers W is disposed within a deposition chamber 300. The susceptor includes a plate 304 whose outer surface is inclined at a small acute angle relative to the vertical. The inclined plate 304 has a plurality of recesses in which wafers W are received, respectively. The plate 304 preferably includes carbon. In that case, the outer surface of the plate includes a coating of silicon carbide (SiC).

The inclination of the plate 304 is sufficient to prevent the wafers W from falling out of the recesses in the plate 304. The recesses may be substantially identical to either of those of the embodiments shown in FIGS. 2-7. In any case, the bottom of each recess has a rounded shape, especially at the outer peripheral portion thereof, so that a wafer W received in the recess makes little contact with the plate 304.

A respective stress-reducing bumper 306 is disposed along the side of each recess and includes material having ductility at a high temperature of, for example, about 1000° C. Preferably, the stress-reducing bumper 306 is of quartz glass. Also, the stress-reducing bumper 306 has a substantially uniform thickness.

A drive mechanism comprising a motor, for example, is connected to the susceptor to rotate the susceptor about a vertical axis. A substantially uniform layer is formed on the wafers W by rotating the susceptor.

A heater 312 is disposed along the side of the chamber 300 to raise the temperature of the wafers W. A controller 313 connected to the heater 312 controls the amount of heat output by the heater 312.

A gas inlet pipe 320 and a manifold or the like are connected to an upper part of the deposition chamber 300 so that deposition gases are introduced into the deposition chamber 300 through the gas inlet pipe 320. The deposition gases introduced into the deposition chamber 300 through the gas inlet pipe 324 flow downwardly over the wafers W for forming a layer on each of the wafers W. A gas outlet pipe 324 is connected to a lower part of the deposition chamber 300 so that by-products generated in the deposition chamber 300 are exhausted from the deposition chamber 300 through the gas outlet pipe 324.

Hereinafter, a process of forming a silicon epitaxial layer on the wafers W will be described.

First, the deposition chamber 300 is heated to a temperature of about 1,000° C. by the heater 312.

Subsequently, silicon wafers W are inserted into the recesses of the plate 304, respectively. The outer peripheral edge of each silicon wafer W rests in contact with only a small portion a stress-reducing bumper 306. The susceptor is then rotated.

A silicon source gas is introduced into the deposition chamber 300 through the gas inlet pipe 320 to form a silicon epitaxial layer on the silicon wafers W. The rotation of the susceptor facilitates the forming of a uniform silicon epitaxial layer on each wafer W.

During the deposition process, each wafer W may expanded radially outwardly into fuller contact with the stress-reducing bumper 306. As was described earlier, the strength and hardness of the material of the stress-reducing bumper 306, e.g., quartz glass, decrease at a temperature of above about 650° C. More particularly, the stress-reducing bumper 306 deforms as the thermally expanding wafer W compresses the stress-reducing bumper 306. Therefore, the force of the impact between the wafer W and the stress-reducing bumper 306 is minimal. Accordingly, defects, such as slip dislocations, are prevented from being produced at the outer peripheral edge of the wafer.

Having thus described the preferred embodiments of the present invention, it is to be understood that the present invention is not limited by particular details set forth in the above description. Rather, many apparent variations thereof are possible within the true spirit and scope thereof as hereinafter claimed.

1. A susceptor comprising:
a plate having at least one recess therein sized to accommodate a wafer; and
a stress-reducing bumper disposed within the recess and extending along the side of the recess, the stress-reducing bumper being more ductile at a temperature than the portion of the plate that delimits the side of the recess.

2. The susceptor of claim 1, wherein the stress-reducing bumper comprises quartz glass.

3. The susceptor of claim 1, wherein the stress-reducing bumper is annular and has a uniform thickness in the radial direction thereof.

4. The susceptor of claim 1, wherein the bottom of the recess has a rounded shape at an outer peripheral portion thereof, whereby the outer edge of a wafer received in the recess will rest against the plate at the outer peripheral portion of the bottom of the recess to minimize an area of contact between the plate and the wafer received in the recess.

5. The susceptor of claimed 4, wherein the plate has an inner bottom wall, and an inclined inner side wall that extends along the outer periphery of the inner bottom wall and subtends an obtuse angle with the inner bottom wall, the inner bottom wall and inclined inner side wall delimiting the bottom of the recess, and wherein the plate also has an inner upright inner side wall that delimits the side of the recess, and a second bottom wall interposed between the inclined inner side wall and the upright inner side wall as extending substantially perpendicular to the upright inner side wall.

6. The susceptor of claim 4, wherein the plate has a projection extending upwardly in the recess at the bottom of the recess, the projection having a rounded profile that imparts the rounded shape to the outer peripheral portion of the bottom of the recess.

7. The susceptor of claim 1, wherein the plate comprises carbon.

8. The susceptor of claim 1, wherein a silicon carbide (SiC) layer extends along a surface of the plate.

9. A deposition apparatus comprising:
a chamber in which a deposition process is performed;
a susceptor disposed in the chamber, the susceptor including a plate having at least one recess in which a wafer is received, and a stress-reducing bumper disposed along the side of the recess, the stress-reducing bumper being more ductile at a temperature than the portion of the plate that delimits the side of the recess;
a heater disposed relative to the susceptor so as to heat the wafer received in each the at least one recess;
a gas inlet pipe connected to the deposition chamber and through which deposition source gas is introduced into the chamber; and
a gas outlet pipe connected to the deposition chamber and through which gas is exhausted from the chamber.

10. The deposition apparatus of claim 9, wherein the stress-reducing bumper comprises quartz glass.

11. The deposition apparatus of claim 9, wherein the stress-reducing bumper is annular and has a uniform thickness in the radial direction thereof.

12. The deposition apparatus of claim 9, wherein the plate comprises carbon.

13. The deposition apparatus of claim 12, wherein a silicon carbide (SiC) layer extends along the surface of the plate.

14. The deposition apparatus of claim 9, wherein the bottom of each the at least one recess has a rounded shape at an outer peripheral portion thereof, whereby the outer edge of a wafer received in the recess will rest against the plate at the outer peripheral portion of the bottom of the recess to minimize an area of contact between the plate and the wafer received in the recess.

15. The deposition apparatus of claim 14, wherein the plate has an inner bottom wall, and an inclined inner side wall that extends along the outer periphery of the inner bottom wall and subtends an obtuse angle with the inner bottom wall, the inner bottom wall and inclined inner side wall delimiting the bottom of the recess, and wherein the plate also has an inner upright inner side wall that delimits the side of the recess, and a second bottom wall interposed between the inclined inner side wall and the upright inner side wall as extending substantially perpendicular to the upright inner side wall.

16. The deposition apparatus of claim 14, wherein the plate has a projection extending upwardly in each the at least one recess at the bottom of the recess, the projection having a rounded profile that imparts the rounded shape to the outer peripheral portion of the bottom of the recess.

17. The deposition apparatus of claim 9, wherein the plate has a plurality of the recesses therein.

18. The deposition apparatus of claim 9, wherein the susceptor is supported for rotation about a vertical axis, and further comprising a driving mechanism operatively connected to the susceptor to rotate the susceptor about the vertical axis.
